(19) United States
(12) Patent Application Publication
(10) Pub. No.: US 2008/0203470 A1
(43) Pub. Date: Aug. 28, 2008

(54) Lateral compensation component

(75) Inventors: Armin Willmeroth, Augsburg (DE); Michael Rueb, Faak am See (AT); Holger Kapels, Holzkirchen (DE); Carolin Tolksdorf, Steinhoering (DE); Giulliano Rocco Aloise, Villach (AT)

Correspondence Address: Davidson, Davidson & Kappel, LLC;Infineon Technologies AG, 485 Seventh Ave, 14th Floor, New York, NY, 10018, US

(73) Assignee: Infineon Technologies Austria AG, Villach (AT)

(21) Appl. No.: 11/712,340

(22) Filed: Feb. 28, 2007

(51) Int. Cl. H01L 29/78; H01L 21/336

(52) U.S. Cl. 257/328; 438/268; 257/E29.255; 257/E21.409

(57) ABSTRACT

A transistor is provided which includes a lateral compensation component. The lateral compensation component includes a plurality of n (or n−) layer/p (or p−) layer pairs, wherein adjacent ones of said pairs are separated by one of an insulator region and/or an intrinsic silicon region.

### FIELD OF THE INVENTION

The present invention relates to the field of compensation components for electrical components.

### BACKGROUND OF THE INVENTION

It is known in the art to use compensation components in high-voltage components in order to improve the ratio between the on-resistance and the breakdown voltage.

In this connection, a distinction is made between two types of high-voltage components: lateral components, on the one hand, and vertical components, on the other. As their names suggest, lateral compensation components are arranged such that the current flow in the driftzone is mainly parallel to the semi-conductor surface, whereas vertical components are arranged such that the current flow in the driftzone is mainly vertical to the semi-conductor surface.

Lateral components offer advantages over vertical components, especially with respect to integration with IC's, because the backsides of both chips can be brought to one potential, for example, to the source potential.

### BRIEF DESCRIPTION OF THE DRAWINGS

FIG. 1(a) shows a top view of a drift path of a lateral compensation transistor.

FIG. 1(b) shows a view through cut-line A of FIG. 1(a) for an exemplary MOSFET.

FIG. 1(c) shows a view through cut-line B of FIG. 1(a) for an exemplary MOSFET.

FIG. 1(d) shows a view through cut-line C of FIG. 1(a) for an exemplary MOSFET.

FIG. 2 shows a top view of a lateral high-voltage MOSFET chip.

FIG. 3 illustrates the etching of a trench in accordance with a method of manufacturing a planar MOSFET cell in accordance with an embodiment of the present invention.

FIG. 4, illustrates deposition or implantation of n− and p− dopant to the planar MOSFET under manufacture.

FIG. 5 illustrates filling the trench of FIGS. 3 and 4 with a dielectric and encapsulation with a thermal oxide and/or nitride.

FIG. 6 illustrates deposition of the gate oxide and polysilicon and patterning of the polysilicon of the planar MOSFET under manufacture.

FIG. 7 illustrates masked p-implantation for a p-tub of the planar MOSFET under manufacture.

FIG. 8 illustrates n-implantation and out-diffusion of the planar MOSFET under manufacture.

FIG. 9 illustrates deposition of intermediate oxide, etching of contact holes and metallization, and back side implantation and backside metalization of the planar MOSFET under manufacture.

FIG. 10 illustrates a top view of a corner of a lateral compensation transistor in accordance with a second embodiment of the present invention.

FIG. 11 shows a section through a planar MOS cell in accordance with a third embodiment of the present invention.

FIG. 12 shows a section through a transistor including a gate trench in accordance with a fourth embodiment of the present invention.

FIG. 13 shows a section through a transistor including a side-wall trench gate in accordance with a fifth embodiment of the present invention.

FIG. 14 shows a section through a transistor including a drift zone which is extended into the substrates in accordance with a sixth embodiment of the present invention.

FIG. 15 illustrates a drift zone including a combination of intrinsic silicon regions and insulator regions for separating compensation layer pairs in accordance with a seventh embodiment of the present invention.

FIG. 16 shows a section through a planar MOSFET including a quasi-intrinsic substrate in accordance with a eighth embodiment of the present invention.

FIG. 17 shows a top view of a drift path in accordance with a ninth embodiment of the present invention which includes a plurality of trenches arranged one behind the other.

FIG. 18 shows a section through a planar MOSFET in accordance with a tenth embodiment of the present invention in which a source side of the chip is electrically isolated by a trench filled with an insulator.

FIG. 19 shows a section through a planar MOSFET in accordance with a eleventh embodiment of the present invention for an SOI substrate.

FIG. 20 shows a section through a planar MOSFET in accordance with a twelfth embodiment of the present invention including an extended drain.

FIG. 21 shows a section through a planar MOSFET in accordance with a thirteenth embodiment of the present invention including an upstream drain.

### DETAILED DESCRIPTION OF THE INVENTION

In accordance an embodiment of the present invention, a transistor (such as a MOSFET) is provided which includes a lateral compensation component. The lateral compensation component includes a plurality of n (or n−) layer/p (or p−) layer pairs, wherein adjacent ones of said pairs can be separated by one of an insulator region and an intrinsic silicon region.

The transistor may include a substrate and an intrinsic silicon region above the substrate, the lateral compensation component being provided in a drift region of the transistor. The drift region may be formed as a trench in the intrinsic silicon region.

In accordance with another embodiment of the present invention, a method for manufacturing a transistor comprises the steps of:(a) providing a workpiece comprising an intrinsic silicon region and a substrate region; (b) forming a trench in the intrinsic silicon region;(c)forming an n (or n−) layer/p (or p−) layer pair in the trench; (d) adding an insulator to the trench or forming an intrinsic silicon region in the trench, the insulator or intrinsic silicon region being adjacent to the n (or n−) layer/p (or p−) layer pair; and(e) forming or adding a source, a drain, and a gate to the transistor. Further, before step (e), steps (c) and (d) may be repeated one or more times.

In accordance with the above-referenced embodiments, an SOI substrate may be provided between the substrate and the intrinsic silicon region. The substrate may be lightly doped (n− or p−). The substrate may also be highly doped (n+ or p+) and may be connected to the source or allowed to float.

In accordance with another aspect of the embodiments described above, the source region of the transistor laterally encloses the drain region of the transistor. In this regard, the source region may include protrusions which extend laterally inward and the drain region includes protrusions which extend laterally outward.

In accordance with other aspects of the embodiments described above, the gate, source, and/or drain may be located in a trench. The trench may be the same trench that includes the drift region, or the gate, source, and/or drain may be located in separate trenches.

In accordance with yet another aspect of the above-referenced embodiments, the drift region may include a plurality of trenches in an intrinsic silicon region, wherein the lateral compensation component includes a plurality of lateral compensation components, each lateral compensation component being disposed in one of the plurality of trenches.

In accordance with various embodiments of the present invention, lateral compensation components, and method of manufacturing the same, are provided in which n (or n−) regions, p (or p−) regions and insulator regions are alternately positioned in the drift zone. The insulator regions can either comprise a separate insulating material, such as silicon dioxide, spin-on-glass (SOG), sol-gel, oxide/nitride combinations and the like or can comprise intrinsic silicon layers.

The lateral compensation structure according to various embodiments of the present invention is advantageous in that the ratio between the on-resistance and the breakdown voltage over a standard component is improved.

Moreover, the insulator regions or intrinsic regions make the geometrical dimensioning of the compensation structures less critical, allowing more freedom in designing components.

In addition, by implementing lateral compensation in a trench with alternating insulator/intrinsic regions, a smaller lateral pitch is possible than with build-up and out-diffusion techniques. Further, this trench compensation technique can be used to implement an irregular lateral compensation pitch.

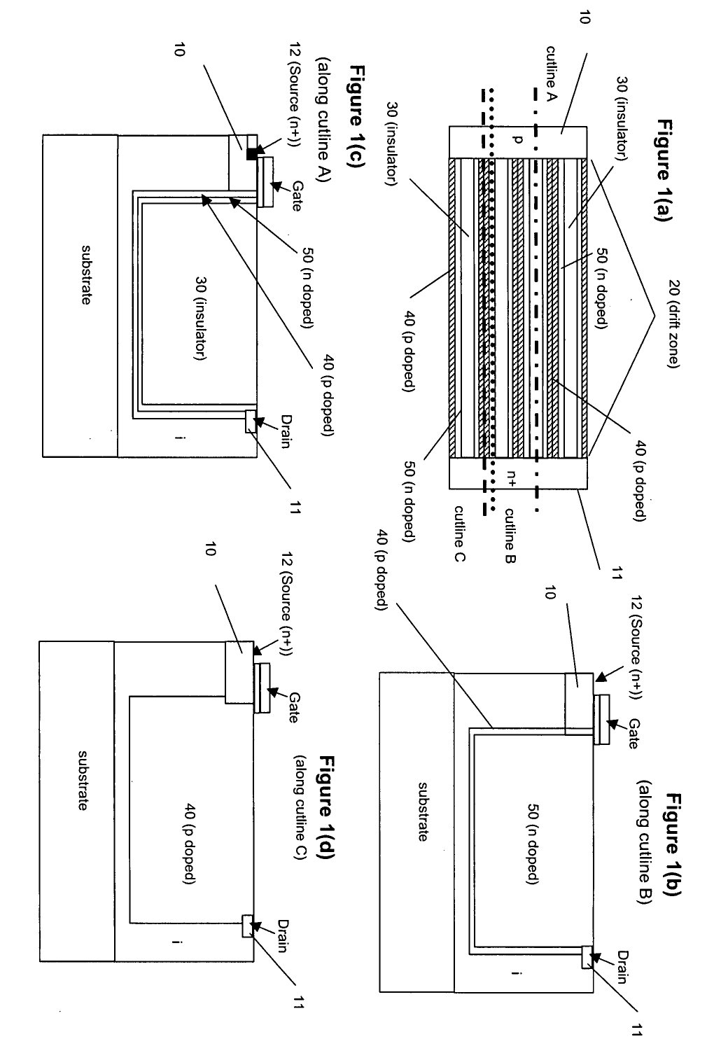

FIG. 1(a) shows a top view of a drift path 20 extending between a p doped region 10 (in which an n+ doped source 12 (not shown) is provided) and n+ doped drain 11 of a lateral compensation transistor 1. Insulator layers 30 are provided between the alternating n compensation regions 50 and p compensation regions 40. The insulator layers 30 have a high breakdown strength, even in the case of blocking, thus separating the individual, mutually compensating n and p layer pairs. Although these insulating layers reduce the active chip area, they allow for simplified geometrical dimensioning of the n and p layers.

FIG. 1(b) shows a view of the lateral compensation transistor of FIG. 1(a) along cutline A (one of the insulation layers of FIG. 1(a)); FIG. 1(c) shows a view of the lateral compensation transistor of FIG. 1(a) along cutline B (one of the n doped compensation layers of FIG. 1(a)); and FIG. 1(d) shows a view of the lateral compensation transistor of FIG. 1(a) along cutline C (one of the p doped compensation layers of FIG. 1(a)). Also shown in FIGS. 1(b) through 1(d) are exemplary source, drain and gate terminals for the transistor.

Although n and p (i.e. medium doped) compensation layers are shown in FIGS. 1(a-d), it should be appreciated that n− and p− (lightly doped) layers may be used if desired. For purposed of the present invention, lightly doped (n− or p−) means below about 1e14 cm⁻³, medium doped (n or p) means between about 1e14 cm⁻³ and about 1e18 cm⁻³; and highly doped (n+ or p+) means above about 1e18 cm⁻³.

In lateral compensation components, inactive edge terminations can be avoided through implementation of a source region which surrounds the drain region. In accordance with a further aspect of such an embodiment, the source and drain regions are interlocked/interdigited.

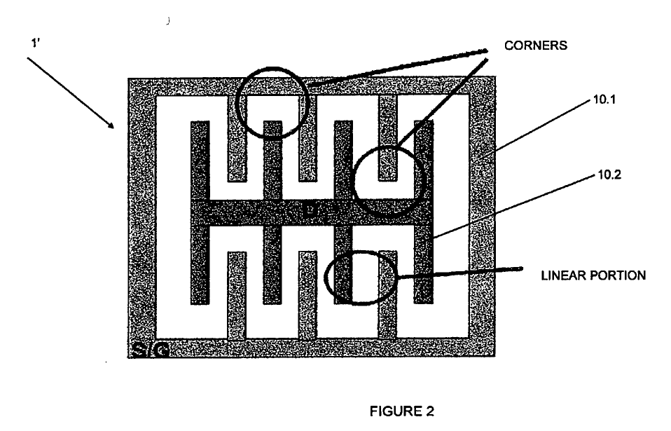

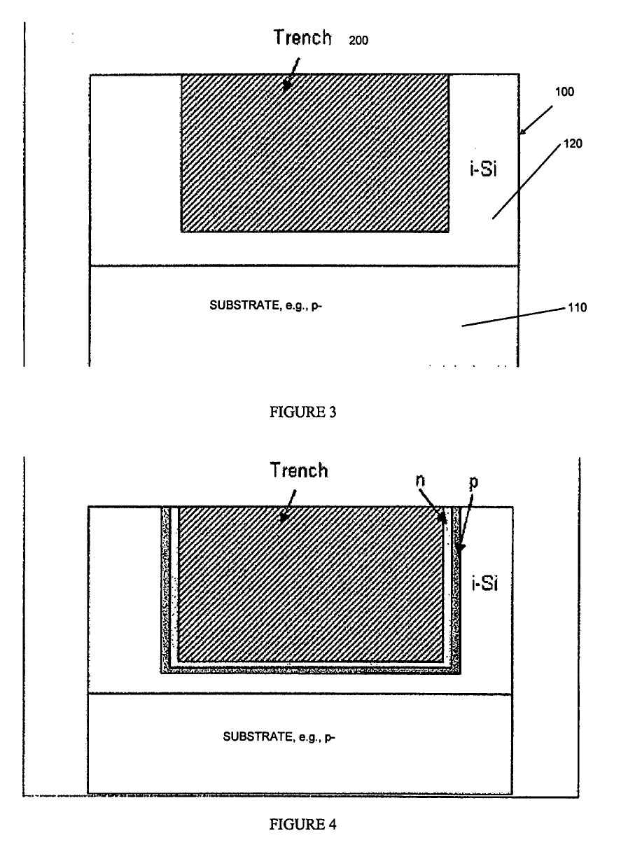

FIG. 2 shows a top view of a lateral high-voltage MOSFET chip which includes a source region surrounding a drain region. The MOSFET 1′ includes a combined source/gate 10.1 surrounding a drain 10.2. A compensation structure, including insulator portions disposed between alternating n compensations regions and p compensation regions, is disposed in the area between source/gate 10.1 and drain 10.2. In this regard, the compensation structure is provided not only along the straight paths (such as those labeled “linear portion”) between source and drain regions, but also in curved regions, such as those labeled “corners.” The use of insulator regions between alternating n compensation and p compensation regions provides increased freedom in the dimensioning of these curved regions, as compared with prior art lateral compensation techniques, without interfering with the compensation.

In prior art lateral compensation components, the depth of the drift zone, the transition from the channel region to the drift path, and the lateral pitch of the compensation structures are critical to attaining an acceptable area specific on-resistance Rₒₙ•A.

The compensation structure in accordance with the present invention has several advantages in this regard. First, the structure can be cost-effectively combined with different transistor cell configurations, such as a trench gate or a planar cell. In addition, the depth of the drift zone and the lateral pitch of the compensation structure can be easily changed without interfering with the compensation. The doping level of the n and p regions can also be changed without having to make further adjustments, provided that doping level is below the breakdown charge.

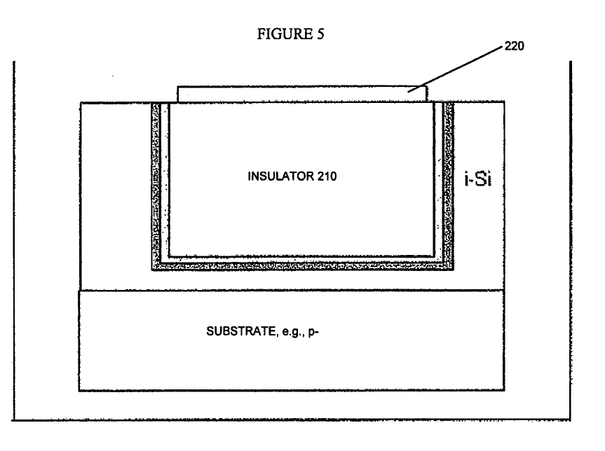

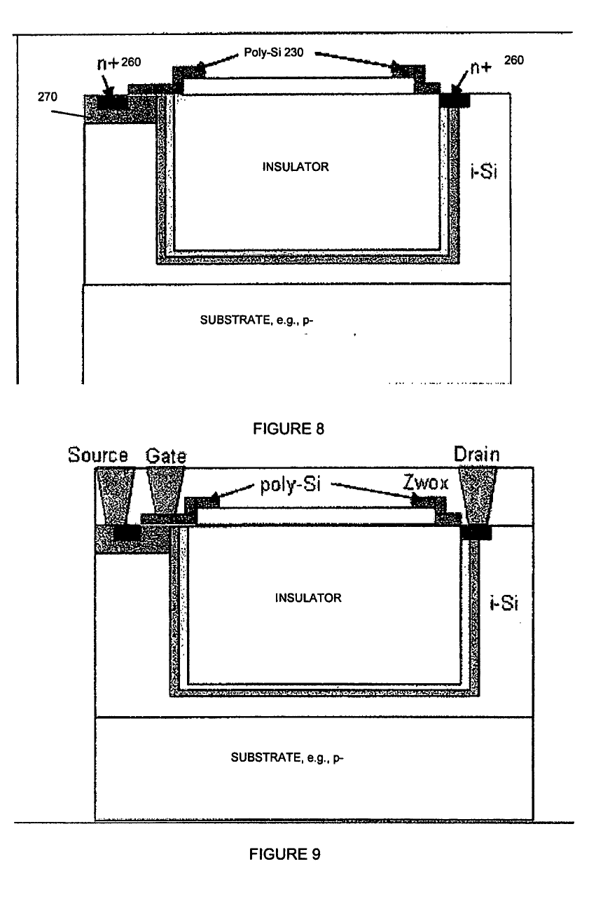

A method of manufacturing a transistor with a lateral compensation component in accordance with the present invention will now be described with reference to a planar MOS cell as shown in FIGS. 3 through 10.

The base material of the planar MOS cell is a lowly doped substrate or a higher-doped material having an undoped or low doped epitaxial layer. A trench is etched in the base material for the compensation structure.

The compensation layers (p compensation, n compensation) are brought in through the trench (e.g, via implantation or vapor-phase deposition) and diffused out of the trench. In this connection, it is initially irrelevant which dopant is diffused out of the trench first. It is only important to always bring in a pair of n and p layers mutually compensating each other. In the case of implantation, it is also possible to use a quad-mode to get a sufficient amount of dopant into the side walls of the trench. It is particularly advantageous if the diffusion lengths of the n and p doped regions are very different, so that two adjacent n and p layers are produced in one out-diffusion step. However, it is also possible to implant the dopants at different depths of the trench side wall or to introduce a thin intrinsic layer between the two vapor-phase deposition steps. Subsequently, the trench is filled with one or more insulator layers.

Additional process steps are then performed according to the transistor cell and insulator layers chosen. If the insulator layers in the trench are to be encapsulated to provide improved reliability against moisture, then this encapsulation step is carried out before the additional process steps. In general, these additional steps include depositing and patterning the gate poly; implanting the p-tub and the contact regions; depositing an intermediate oxide, and etching and plating the contact holes.

Possible insulator materials include, but are not limited to: silicon dioxide (CVD and thermal), spin-on-glass (SOG), sol-gel, oxide/nitride combinations, and the like.

FIG. 3 illustrates the etching of a trench in accordance with a method of manufacturing a planar MOSFET cell in accordance with an embodiment of the present invention. A substrate 100 includes an intrinsic silicon (i-Si) portion 120 into which a trench is to be etched, and another substrate portion 110, which need not be intrinsic, and may for example be p-doped, n-doped, or intrinsic. A trench 200 is etched into i-Si portion 120.

Turning to FIG. 4, after the trench 200 is etched, illustrates deposition or implantation of n− and p− dopant to the planar MOSFET under manufacture to provide the n compensation and p compensation regions. A variety of techniques can be used to create these compensation regions. For example, n and p dopants can be deposited from a vapor phase or implanted for example using the quad-mode. The n and p dopants can also be achieved through out-diffusion.

FIG. 5 illustrates filling the trench of FIGS. 3 and 4 with an insulator material 210 such as dielectric (e.g., silicon dioxide). The insulator material 210 can then be encapsulated with an encapsulation material 220 such as thermal oxide and/or nitride. The oxide is then patterned as illustrated.

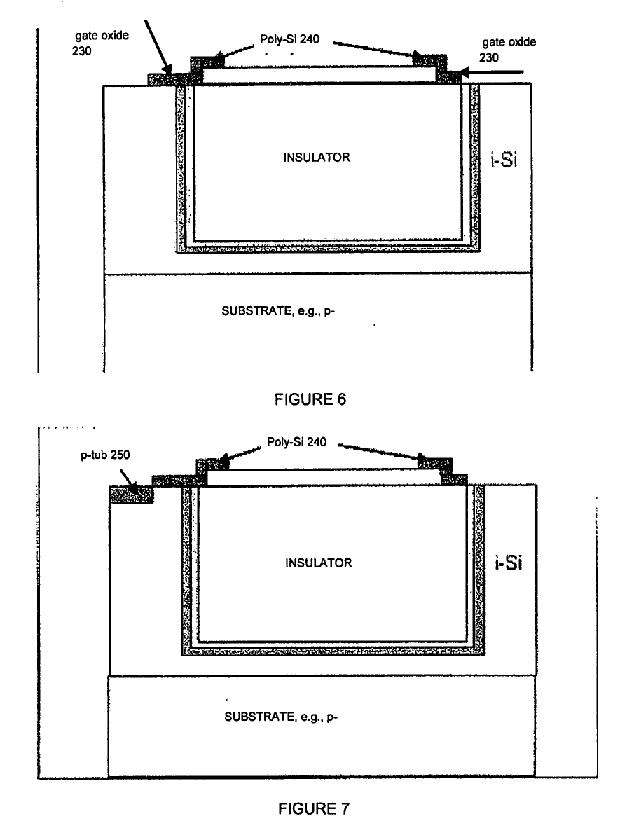

Referring to FIG. 6, deposition of the gate oxide 230 is then performed, followed by deposition of polysilicon 240, and patterning of the polysilicon 240.

Masked p implantation for a p tub 240 of the planar MOSFET under manufacture is then performed as illustrated in FIG. 7.

Alternatively, n+ and p+ regions may be implanted via a spacer. FIG. 9 illustrates n+ implantation and out-diffusion 260 on a spacer 270.

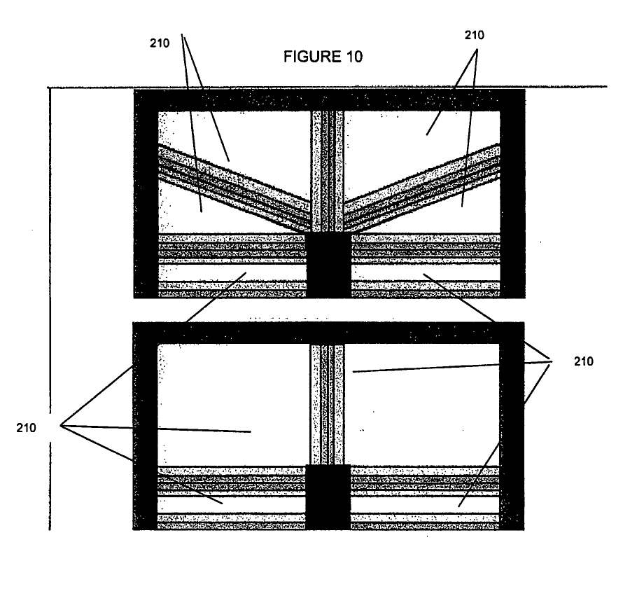

In any event, the method then performs deposition of intermediate oxide, etching of contact holes and metallization, and back side implantation and backside metalization of the planar MOSFET under manufacture, as illustrated in FIG. 10.

Referring again to FIG. 1, in accordance with an alternative embodiment of the present invention, intrinsic layers can be introduced between the n and p compensation layer pairs, instead of the insulator layers 30. These intrinsic regions, like the insulator layers 30 have a higher breakdown voltage than the doped regions and can therefore be dimensioned independently of the compensation layers. This embodiment has the advantage of a possible improvement of the on-resistance, because the n layer can partly diffuse into the intrinsic region. Further advantages are the reduction of mechanical stress in the wafer when the regions of higher blocking capacity are filled with intrinsic silicon, and the reduction of leakage losses at the interface between the silicon and the oxide.

FIG. 10 illustrates a top view of a corner of a lateral compensation transistor in accordance with a second embodiment of the present invention. In the corners, the insulator layers can be enlarged without reducing their breakdown voltage. This makes the dimensioning of the corners very easy. In order to prevent mechanical stress caused by the oxide filling, intrinsic regions, rather than insulator layers, can be introduced between the compensation layers. The number of compensation layers shown in the figure only serves as an example and may be increased.

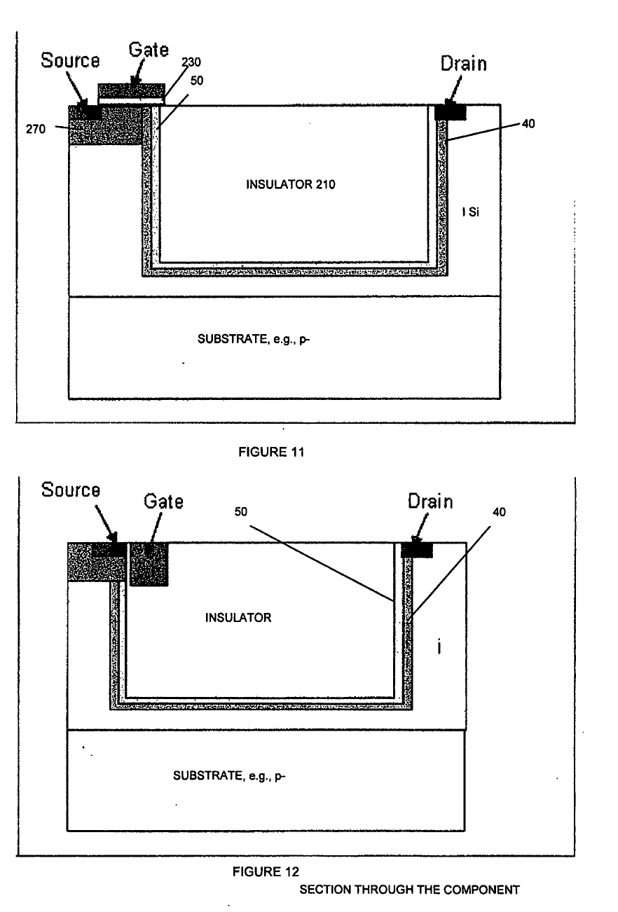

FIG. 11 shows a section through a planar MOS cell in accordance with a third embodiment of the present invention. The MOSFET cell includes a source, drain, and gate. As illustrated, the cell includes an intrinsic silicon region (i-Si) over a substrate, a p doped layer 40, an n doped layer 50, an insulator layer 210, and a gate oxide 230 disposed between the gate and the n and p layers. The locations of the p and n layers can, of course, also be reversed. Further, the insulator 210 can be implemented as an intrinsic region. It is also conceivable to provide a plurality of MOS channels in order to increase the channel width.

FIG. 12 shows a section through a transistor including a gate trench in accordance with a fourth embodiment of the present invention. The transistor of FIG. 13 is similar to the transistor of FIG. 12, except that the gate is located in the trench. The advantage of this arrangement lies in the space-saving arrangement of the gate, which also allows the gate pad to be disposed above the drift zone trench. Another advantage is the improved current distribution from the channel into the driftzone.

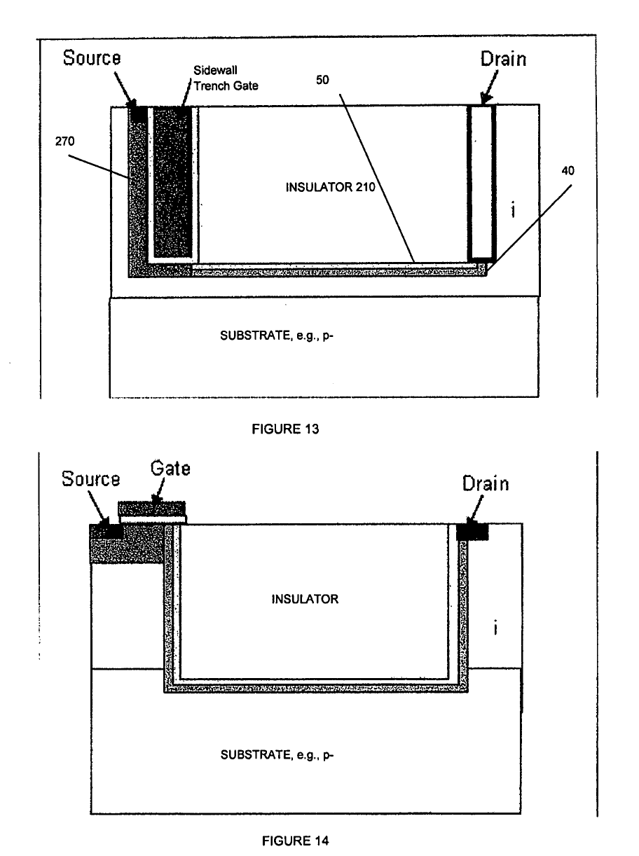

FIG. 13 shows a section through a transistor including a side-wall trench gate in accordance with a fifth embodiment of the present invention, with similar components bearing the same reference numerals as the preceding figures, including p layer 40, n layer 50, spacer 270, and insulator 210 (or, an alternative, an intrinsic region 210). Side-wall trench gates are known in the art, as described for example in DE19818300. Referring to FIG. 14, a transistor is shown including a gate placed in a trench. The trench may be the trench for the drift zone, or be located in as separate trench as shown. The drain contact may either have a planar configuration or be designed as a trench (as shown).

As illustrated in FIG. 14, in accordance with a sixth embodiment of the present invention, a transistor including the lateral compensation component in accordance with the present invention, can include a drift zone which is extends into the substrate.

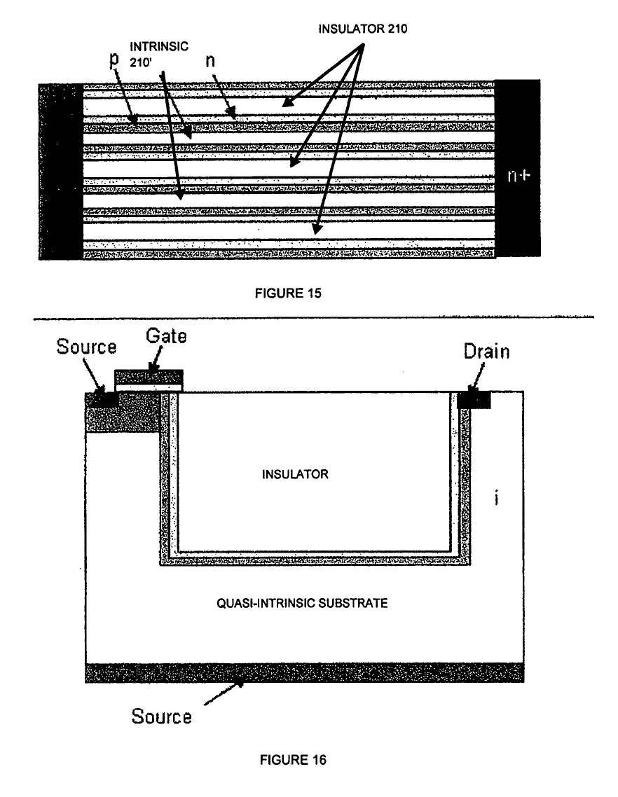

In the embodiments described above, the lateral compensation component has included either an insulator layer or an intrinsic silicon region. However, as illustrated in FIG. 15, the lateral compensation component can also include a combination of intrinsic silicon regions 210′ and insulator layers or regions 210 in the drift zone for separating compensation layer pairs in accordance with a seventh embodiment of the present invention.

FIG. 16 shows a section through a MOSFET including a quasi-intrinsic substrate in accordance with a eighth embodiment of the present invention. The quasi-intrinsic substrate is made of a quasi-intrinsic material such as, for example, FZ (float zone) material. In addition, a highly-doped region (n+ or p+ as desired) can be implanted on the backside of the MOSFET for connecting the quasi-intrinsic substrate to the source of the MOSFET, for example. Alternatively, the backside of the MOSFET can remain floating.

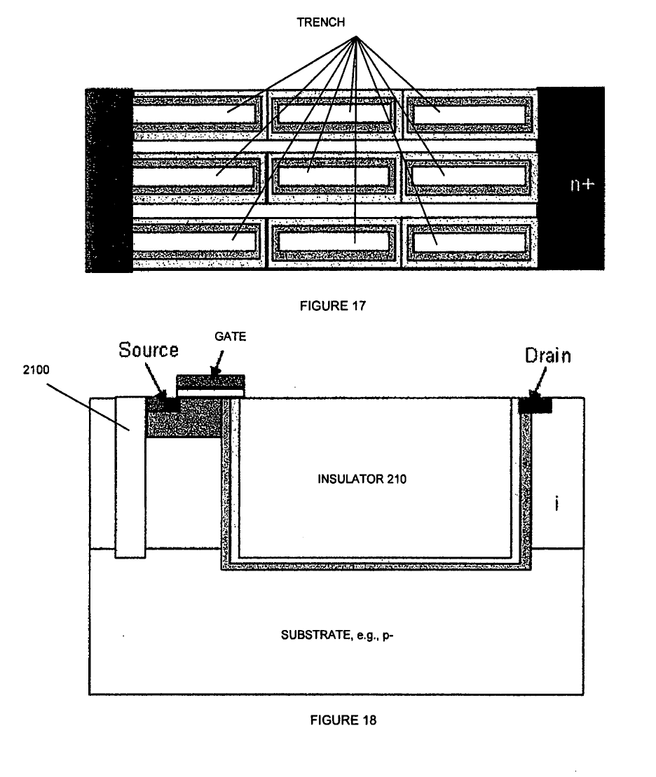

In accordance with a ninth embodiment of the present invention, a transistor such as a MOSFET can include a plurality of trenches arranged one behind the other for the drift path. FIG. 17 illustrates such an embodiment, with nine rectangular trenches arranged one behind the other. However, a transistor according to this embodiment may include any arrangement of strips, a square or hexagonal pattern, and also a combination of trenches of different sizes. It is only important that a continuous n-layer exists upon completion of the transistor. Thus, it is also possible to produce a variable degree of compensation from the source to drain by varying the degree of doping from one trench to another.

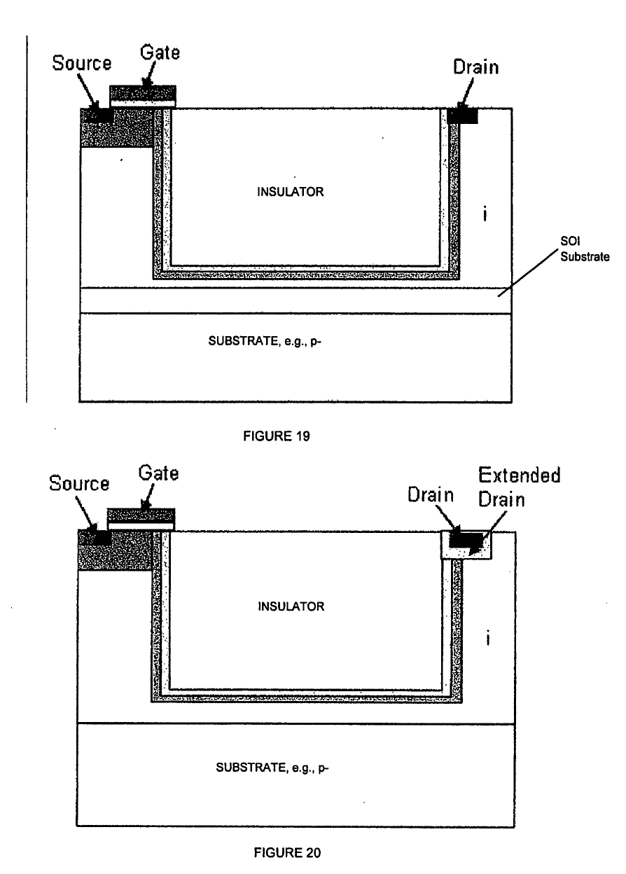

FIG. 18 shows a section through a transistor in accordance with a tenth embodiment of the present invention. In this embodiment, a source side of the chip is electrically isolated by a trench filled with an insulator 2100. Through the inclusion of such an insulator 2100, the space charge region (also referred to as the depletion region) of a high voltage MOSFET component can reliably prevented from meeting the sawn (or cut) edge of along which an individual IC chip is separated from the wafer. Dopant can also be diffused out of the isolation trench as in the case of the main trench without impairing the function of this isolation trench.

FIG. 19 shows a section through a MOSFET in accordance with an eleventh embodiment of the present invention. In accordance with this embodiment, the compensation structure in accordance with the present invention is implemented in a MOSFET including an SOI (silicon on insulator) substrate. An isolation trench (not shown) may also be included.

FIG. 20 shows a section through a MOSFET in accordance with a twelfth embodiment of the present invention. In this embodiment, the compensation structure in accordance with the present invention is implemented with an extended drain. The extended drain is advantageous in that it reduces the electric field peak on the drain side.

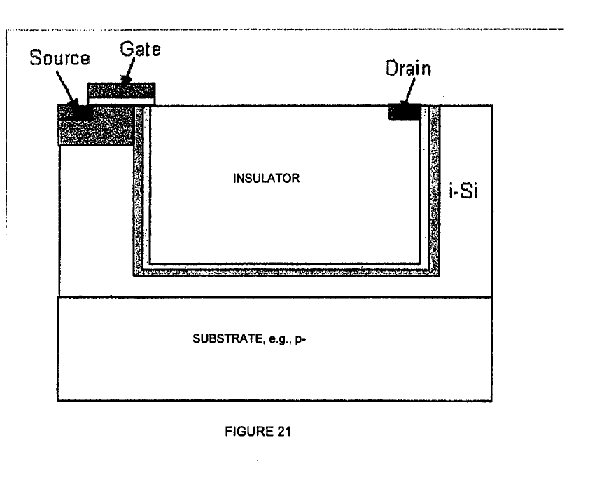

FIG. 21 shows a section through a MOSFET in accordance with a thirteenth embodiment of the present invention. In accordance with this embodiment, the compensation structure in accordance with the present invention is implemented with an upstream drain. In this regard, the drain is “upstream” in that it is located in the drift zone trench. An upstream drain is advantageous in that it avoids or reduces the electric field peak on the drain side.

In the preceding specification, the invention has been described with reference to specific exemplary embodiments and examples thereof. It will, however, be evident that various modifications and changes may be made thereto without departing from the broader spirit and scope of the invention as set forth in the claims that follow. The specification and drawings are accordingly to be regarded in an illustrative manner rather than a restrictive sense.

1. A transistor comprising a lateral compensation component, the lateral compensation component including a plurality of n layer/p layer pairs or a plurality of n-layer/p-layer pairs, adjacent ones of said pairs being separated by one of an insulator region and an intrinsic silicon region.

2. The transistor of claim 1, wherein a source region of the transistor laterally encloses a drain region of the transistor.

3. The transistor of claim 2, wherein the source region includes protrusions which extend laterally inward and the drain region includes protrusions which extend laterally outward.

4. The transistor of claim 1, wherein some adjacent pairs are separated by insulator regions and other adjacent pairs are separated by intrinsic silicon regions.

5. A transistor comprising:
a substrate, a source, a drain, a gate, and a drift region, the drift region including a lateral compensation component, the lateral compensation component including a plurality of n layer/p layer pairs or a plurality of n-layer/p-layer pairs, adjacent ones of said pairs being separated by one of an insulator region and an intrinsic silicon region.

6. The transistor of claim 5, wherein the substrate is below the drift region.

7. The transistor of claim 5, wherein the drift region is in a trench in an intrinsic silicon region, the intrinsic silicon region located over the substrate.

8. The transistor of claim 7, wherein the gate is in the trench.

9. The transistor of claim 7, wherein the drain is in the trench.

10. The transistor of claim 5, wherein the drain is n+ doped.

11. The transistor of claim 5, wherein the drain is p+ doped.

12. The transistor of claim 5, wherein the source is n+ doped.

13. The transistor of claim 5, wherein the source is p+ doped.

14. The transistor of claim 5, wherein the substrate is n− doped.

15. The transistor of claim 5, wherein the substrate is p− doped.

16. The transistor of claim 5, wherein the source laterally encloses the drain.

17. The transistor of claim 5, wherein the source includes a source region and the drain includes a drain region, the source region including protrusions which extend laterally inward and the drain region including protrusions which extend laterally outward.

18. The transistor of claim 7, further comprising a spacer in the trench.

19. The transistor of claim 7, wherein the gate is located in a gate trench.

20. The transistor of claim 19, wherein the source is located in a source trench.

21. The transistor of claim 20, wherein the drain is located in a drain trench.

22. The transistor of claim 7, wherein the trench extends through the intrinsic silicon region and into the substrate.

23. The transistor of claim 5, wherein the substrate is highly doped.

24. The transistor of claim 23, wherein the highly doped substrate is connected to the source.

25. The transistor of claim 5, wherein the drift region includes a plurality of trenches in an intrinsic silicon region, wherein the lateral compensation component includes a plurality of lateral compensation components, each lateral compensation component being disposed in one of the plurality of trenches.

26. The transistor of claim 7, further comprising an SOI substrate between the substrate and the intrinsic silicon region.

27. The transistor of claim 5, further comprising an extended drain surrounding the drain.

28. The transistor of claim 5, wherein some adjacent pairs are separated by insulator regions and other adjacent pairs are separated by intrinsic silicon regions.

29. The transistor of claim 5 wherein at least one of the adjacent pairs are separated by an instrinic silicon region and a insulator region.

30. The transistor of claim 1 wherein at least one of the adjacent pairs are separated by an instrinic silicon region and a insulator region.

31. A method for manufacturing a transistor, comprising the steps of:
(a) providing a workpiece comprising an intrinsic silicon region and a substrate region;
(b) forming a trench in the intrinsic silicon region;
(c)forming an n layer/p layer pair or an n-layer/p-layer pair in the trench;
(d) adding an insulator to the trench or forming an intrinsic silicon region in the trench, the insulator or intrinsic silicon region being adjacent to the n channel/p channel pair;
(e) forming or adding a source, a drain, and a gate to the transistor.

32. The method of claim 31, wherein, prior to step (e), the method comprises repeating steps c and d at least once.
